(19) United States
(12) Patent Application Publication
(10) Pub. No.: US 2017/0184687 A1
(43) Pub. Date: Jun. 29, 2017

(54) Sensor

(71) Applicant: EPCOS AG, Muenchen (DE)

(72) Inventors: Bernhard Ostrick, Teltow (DE); Wolfgang Schreiber-Prillwitz, Froendenberg (DE)

(73) Assignee: EPCOS AG, Muenchen (DE)

(21) Appl. No.: 15/325,418

(22) PCT Filed: Jul. 6, 2015
(86) PCT No.: PCT/EP2015/065358

§ 371 Date: Jan. 10, 2017

(30) Foreign Application Priority Data
Jul. 10, 2014 (DE) 10 2014 109 701.7

(51) Int. Cl. G01R 33/00; G01R 33/09; G01R 33/038

(52) U.S. Cl. CPC G01R 33/0005; G01R 33/0047; G01R 33/038; G01R 33/093

(57) ABSTRACT

A sensor is disclosed. In an embodiment, the sensor includes a fixed structure, a movable structure movable relative to the fixed structure, a magnet configured to generate a magnetic field and a first magnetically sensitive element configured to determine the magnetic field at a position of the first magnetically sensitive element. The magnet is fastened to the fixed structure and the first magnetically sensitive element is fastened to the movable structure. Alternatively, the magnet is fastened to the movable structure and the first magnetically sensitive element is fastened to the fixed structure.

This patent application is a national phase filing under section 371 of PCT/EP2015/065358, filed Jul. 6, 2015, which claims the priority of German patent application 10 2014 109 701.7, filed Jul. 10, 2014, each of which is incorporated herein by reference in its entirety.

### TECHNICAL FIELD

The present invention relates to a sensor. The sensor may be, in particular, a sensor in which a measurement variable is determined on the basis of a deflection of a movable structure in relation to a fixed structure. A measurement principle of this kind is used, for example, in motion sensors, pressure sensors or rate of rotation sensors.

### BACKGROUND

In many applications, sensors for measuring different sensor variables are combined with one another, for example, in inertial sensors, which determine three to six degrees of freedom (DOF), and in motion sensors, which determine six to ten degrees of freedom. If these sensors have signal conversion principles which differ from one another, this can lead to increased complexity in terms of system design and signal processing. It would therefore be desirable for different types of sensor to allow standardized signal conversion.

Furthermore, owing to increasing miniaturization in many technical fields, it is also critical to continue to miniaturize sensors, without the measurement accuracy being adversely affected in the process.

### SUMMARY OF THE INVENTION

Embodiments of the invention provide an improved sensor which provides at least one of the abovementioned advantages.

Various embodiments provide a sensor which has a fixed structure, a movable structure which can move relative to the fixed structure, a magnet which generates a magnetic field, and a first magnetically sensitive element which is configured to determine the magnetic field at the position of said first magnetically sensitive element, wherein the magnet is fastened to the fixed structure and the first magnetically sensitive element is fastened to the movable structure, or wherein the magnet is fastened to the movable structure and the first magnetically sensitive element is fastened to the fixed structure.

The sensor may be a microcomponent, in particular an MEMS component (MEMS=microelectromechanical system). The sensor may be, for example, a pressure sensor, an acceleration sensor or a rate of rotation sensor. The sensor can also be used in a microphone for converting sound waves into an electrical signal, wherein the sound waves deflect a movable structure which is configured as a diaphragm.

Since either the magnet or the magnetically sensitive element is fastened on the movable structure and, furthermore, the respectively other element is fastened on the fixed structure, a conclusion can be drawn about the relative position of the movable structure in relation to the fixed structure from the relative position of the magnet and of the magnetically sensitive element. In particular, the magnet and the first magnetically sensitive element can be connected to the movable structure and the fixed structure in such a way that a movement of the movable structure relative to the fixed structure leads to a corresponding relative movement of the magnet in relation to the first magnetically sensitive element. Accordingly, the magnetic field at the location of the first magnetically sensitive element changes depending on the relative position of the movable structure in relation to the fixed structure.

This configuration of the sensor provides a high level of freedom of design in respect of the positioning of the magnetically sensitive element and the magnet.

In the case of capacitive sensors, the sensitivity and the signal-to-noise ratio is highly dependent on the size of the capacitive structure. A capacitive sensor with a high degree of measurement accuracy therefore requires a specific minimum size. The present sensor overcomes this disadvantage since the magnetically sensitive element and the magnet can be very small, without the degree of measurement accuracy falling in the process. Therefore, the present sensor can have a very high degree of miniaturization and accordingly only a very small space requirement.

The magnetically sensitive element can be configured to determine the field strength of the magnetic field and/or the field direction of the magnetic field at the position of said magnetically sensitive element. To this end, the magnetically sensitive element can make use of, for example, the Hall effect or a magnetoresistive effect.

A magnetoresistive effect is any effect which describes the change in an electrical resistance of a material by applying an external magnetic field. Said effects include, in particular, the anisotropic magnetoresistive effect (AMR effect), the giant magnetoresistance effect (GMR effect), the colossal magnetoresistive effect (CMR effect), the tunnel magnetoresistance effect (TMR effect) and the planar Hall effect. The magnetically sensitive element can ascertain the magnetic field strength and/or the magnetic field direction at the position of said magnetically sensitive element using said magnetoresistive effects.

The sensor can be configured to ascertain the relative position of the movable structure in relation to the fixed structure by determining the magnetic field at the position of the magnetically sensitive element. This measurement principle has the major advantage that it can be used for any type of sensors in which a movable structure is moved relative to a fixed structure. The measurement principle can be used, for example, in sensors for measuring pressure, movement, acceleration or rates of rotation.

Each of these sensors which uses the above-described measurement principle can further be combined with similar signal processing. Since this measurement principle can be used for different sensors, the measurement principle allows a standardized signal conversion principle to be used for different sensors.

Sensors which determine an absolute position on the basis of measurement of the Earth's magnetic field also have a magnetically sensitive element, and therefore the same circuit for signal processing can be used for this type of sensor too.

The sensor can have at least one second magnetically sensitive element which is configured to determine the magnetic field at the position of said second magnetically sensitive element. The position of the movable structure relative to the fixed structure can be unambiguously determined by using at least two magnetically sensitive elements. The relative position can be ascertained in all three directions in space given a correspondingly apt arrangement of the two magnetically sensitive elements and of the magnet. In alternative exemplary embodiments, the relative position can be unambiguously determined at least in two directions in space.

In particular, the first and the second magnetically sensitive element can either both be fastened on the movable structure or both be fastened on the fixed structure. The magnet can then be fastened on the respectively other structure. In this case, a conclusion can be drawn about the relative position of the movable structure in relation to the fixed structure from the relative position of the magnet and the two magnetically sensitive elements. In particular, the magnet and the two magnetically sensitive element can be connected to the movable structure and the fixed structure in such a way that a movement of the movable structure relative to the fixed structure leads to a corresponding relative movement of the magnet in relation to the two magnetically sensitive element. Accordingly, the magnetic field at the location of the first magnetically sensitive element and the magnetic field at the location of the second magnetically sensitive element change depending on the relative position of the movable structure in relation to the fixed structure.

In some configurations, the sensor has four magnetically sensitive elements. Said magnetically sensitive elements can be interconnected by means of a Wheatstone measuring bridge, as a result of which the data which is measured by the structures can be read and evaluated in a particularly simple manner. The four magnetically sensitive elements can be arranged either on the movable structure or on the fixed structure.

The first and the second magnetically sensitive element can be arranged in one plane. In this case, the two magnetically sensitive elements can either both be arranged on the fixed structure or both on the movable structure. The plane can be, in particular, parallel to a plane in which the movable structure extends in its undeflected state. If the movable structure is, for example, a diaphragm, the diaphragm lies in one plane in a state in which the diaphragm is not deflected, wherein the first and the second magnetically sensitive element can be arranged either in the same plane as the diaphragm or can lie in a plane which is parallel to the plane which is defined by the diaphragm.

Further magnetically sensitive elements can be arranged next to the first and the second magnetically sensitive elements in the plane. The arrangement of the first and of the second magnetically sensitive element in the plane allows at least the position of the movable structure within the plane to be accurately determined.

Furthermore, the magnet can be arranged outside the plane when the movable structure is in an undeflected state. In this case, the sensor can unambiguously ascertain the position of the movable structure in all three directions in space.

The sensor can furthermore have a stop which limits the movement options of the movable structure in such a way that the magnet is always located on a first side of the plane or in the plane. As an alternative to the stop, the sensor can also have a structure of different configuration which limits the movement options of the movable structure in such a way that the magnet is always located on a first side of the plane or in the plane.

In this way, it is possible to prevent the magnet from moving to a second side of the plane. Therefore, ambiguities cannot occur during position determination. The first side may be a top side or bottom side of the plane. The top side of the plane is defined by the magnet or the magnetically sensitive elements being arranged on the movable structure on said side. Furthermore, the bottom side of the plane can correspond to that side of the movable structure which is free of the magnetically sensitive elements or the magnet.

Furthermore, the sensor can have a further magnetically sensitive element which is configured to determine the magnetic field at the respective position of said further magnetically sensitive element, wherein the further magnetically sensitive element is arranged outside the plane in which the first and the second magnetically sensitive element are arranged. In this way, the position of the movable structure relative to the fixed structure can be unambiguously determined in all three directions in space, without it being necessary to limit the movement options of the movable structure. Accordingly, a larger measurement region can be covered.

The movable structure may be, for example, a diaphragm or a seismic mass. The diaphragm can be moved, for example, relative to a frame which surrounds the diaphragm in one plane, wherein the frame forms the fixed structure. The seismic mass can be formed from silicon microstructures.

The sensor can be configured to excite the movable structure to oscillate. If the movable structure is excited to oscillate, rates of rotation can be measured with the aid of the sensor.

Various ways of exciting the movable structure to oscillate are feasible. The movable structure can be a seismic mass which is suspended from a beam, wherein the seismic mass can execute bending and/or torsional oscillations. The movable structure can be designed as an electrode or can be connected to electrode structures and can be electrostatically excited to oscillate by means of the electrode structures. The movable structure can be designed as an electrode or can have electrode structures and furthermore can have a piezoelectric film and can be excited to oscillate with the aid of the electrode structures and the piezoelectric film.

The magnet can be a structured thin-film permanent magnet. The magnet can have a length and a width, wherein the ratio of length to width is not equal to one. This ratio is also called the aspect ratio of the magnet. The magnet can accordingly be designed in a rod-like or ellipsoidal manner. A magnet of this kind generates a magnetic field which has a lower degree of symmetry than the magnetic field of a magnet with an aspect ratio of one, and therefore the position of the magnetically sensitive element relative to the magnet can be determined more easily.

The magnet can have a coil through which current flows. Accordingly, said magnet may be a solenoid which can be switched on and switched off.

Furthermore, the sensor can have a second movable structure which can move relative to the fixed structure. The sensor can also have a further magnet which generates a further magnetic field, and an additional magnetically sensitive element which is configured to determine the further magnetic field at the position of said additional magnetically sensitive element. The further magnet can be fastened to the fixed structure and the additional magnetically sensitive element can be fastened to the second movable structure or, alternatively, the further magnet can be fastened to the second movable structure and the additional magnetically sensitive element can be fastened to the fixed structure.

Therefore, in this way, two movable structures can be combined with one another, this allowing several measurement variables to be ascertained at the same time. By way of example, an acceleration can be measured by means of the first movable structure, the first magnetically sensitive element and the first magnet, and a rate of rotation can be measured by means of the second movable structure, the additional magnetically sensitive element and the further magnet.

Furthermore, yet more magnetically sensitive elements can be fastened to the second movable structure. In particular, all embodiments which are disclosed here in connection with the first movable structure and the fixed structure are possible for the second movable structure and the fixed structure.

A height or an absolute position can also be determined using a sensor in which a relative position of a magnet and a magnetically sensitive element is determined.

Since all of the degrees of freedom which are ascertained in this way are each determined by the relative position of a magnet in relation to a magnetically sensitive element, a standardized reading electronics system can be used. Therefore, the subsequent signal processing can be simplified. In particular, the same signal paths can be used for all of the measurement variables. As a result, the complexity of design of an ASIC (application specific integrated circuit) is reduced. Furthermore, a function test of the ASIC is also considerably simplified.

An electrode structure can be formed on the fixed structure and on the second movable structure and to this end can be configured to excite the second movable structure to oscillate. In this case, either the fixed structure or the second movable structure can be composed of a conductive material and therefore form the electrode structure itself or an electrode structure can in each case be mounted on the fixed structure and of the second movable structure.

Accordingly, the second movable structure can be used to measure a rate of rotation. The first movable structure can be used to measure a movement. This results in a sensor which is suitable for determining six degrees of freedom.

Furthermore, the sensor can have structures for measuring the direction of the Earth's magnetic field and/or structures for measuring a pressure. An absolute position can be determined by determining the Earth's magnetic field. As an alternative or in addition, an orientation to the Earth's magnetic field, which orientation can be used to determine an orientation of the sensor, the so-called heading, can be ascertained by determining the Earth's magnetic field. Therefore, the sensor can ascertain three further degrees of freedom. The height can be determined by measuring the pressure, and therefore the sensor can ascertain a further degree of freedom. Therefore, the sensor described here can determine 10 degrees of freedom in total. All of these degrees of freedom can be ascertained by the relative position of a magnet in relation to a magnetically sensitive element, wherein either the magnet or the magnetically sensitive element is arranged on a fixed structure and the respectively other element selected from the group comprising the magnet and the magnetically sensitive element is arranged on the movable structure. Therefore, identical signal processing means can be used to determine each degree of freedom.

Furthermore, the Earth's magnetic field can disrupt the measurements of inertial sensors and rate of rotation sensors. If it is measured separately, this disruption can be corrected and accuracy of the other measurements can be increased in this way.

Furthermore, a plurality of the above-described sensors can be combined to form a sensor arrangement. By way of example, at least two of the following sensors can be combined with one another, said sensors being selected from the group comprising a first sensor which determines an acceleration with three degrees of freedom, a second sensor which determines a rate of rotation with three degrees of freedom, a third sensor which determines the Earth's magnetic field with three degrees of freedom, and a fourth sensor which determines a height by means of a pressure measurement. Each of these sensors can have a magnetically sensitive element. In particular, the first, second and fourth sensors can have a magnetically sensitive element and a magnet, one element of which is arranged on a movable structure and the other element of which is arranged on a fixed structure. The third sensor can likewise have a magnetically sensitive element.

Furthermore, in this sensor arrangement, up to seven different movable structures and three static structures for measuring the Earth's magnetic field can be combined with one another and, for example, integrated in a single chip. In particular, three of the seven movable structures can each measure one coordinate of an acceleration in this case, three further structures of the seven movable structures can each measure one coordinate of a rate of rotation in this case, the seventh movable structure can measure a pressure, and therefore a height, and the three static structures can measure the Earth's magnetic field and therefore an absolute position.

Since the relative position of the movable structures in relation to an associated fixed structure can in each case be determined by means of a magnetically sensitive element and the Earth's magnetic field is also determined by means of magnetically sensitive elements, the chip can be combined with a standardized reading electronics system which uses the same signal conversion principle for all of the sensors.

Furthermore, the number of movable structures can be reduced by the deflection of a movable structure in various directions in space being detected by a plurality of magnetically sensitive elements. Further miniaturization is possible in this way.

In one embodiment, the movable structure can extend in one plane in an undeflected state, wherein one of the elements selected from the group comprising the magnetically sensitive element and the magnet is arranged in the plane and the other element selected from the group comprising the magnetically sensitive element and the magnet is arranged outside the plane. In this case, a state in which no force acts on the movable structure can be called the undeflected state. The undeflected state can be an inoperative state of the movable structure.

### BRIEF DESCRIPTION OF THE DRAWINGS

The present invention will be described more precisely below with reference to figures.

FIG. 1 shows a first exemplary embodiment of a sensor;

FIG. 2 shows a second exemplary embodiment of a sensor;

FIG. 3 shows a third exemplary embodiment of a sensor;

FIG. 4 shows a fourth exemplary embodiment of a sensor;

FIG. 5 shows a fifth exemplary embodiment of a sensor;

FIG. 6 shows a sixth exemplary embodiment of a sensor; and

FIG. 7 shows a seventh exemplary embodiment of a sensor.

### DETAILED DESCRIPTION OF ILLUSTRATIVE EMBODIMENTS

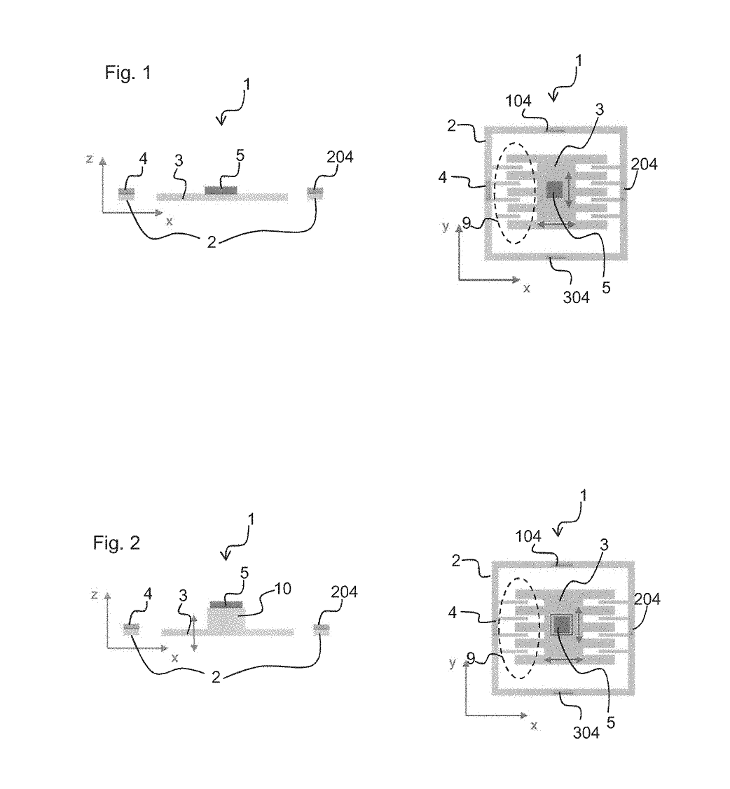

FIG. 1 shows a sensor 1. The sensor 1 has a fixed structure 2 and a movable structure 3 which can move relative to the fixed structure 2.

The sensor 1 is configured to measure a movement of the movable structure 3 relative to the fixed structure 2. This sensor concept is used, for example, in pressure sensors in which the deflection of a diaphragm relative to a frame is measured. Accordingly, the movable structure 3 may be the diaphragm, and the fixed structure 2 may be the frame. Other sensors, for example, sensors for measuring accelerations or sensors for measuring rates of rotation, are also based on the measurement of the deflection of a movable structure 3 relative to a fixed structure 2. The movable structure 3 may be a seismic mass.

In the exemplary embodiment illustrated in FIG. 1, the movable structure 3 is a diaphragm. Furthermore, the fixed structure 2 is a frame.

The sensor 1 shown in FIG. 1 is an inertial sensor for measuring accelerations. The movable structure 3 is fastened to the fixed structure 2 in such a way that said movable structure can move relative to the fixed structure 2 in every direction in space. To this end, the movable structure 3 is suspended from the fixed structure 2 by way of spring elements (not shown).

Furthermore, the sensor 1 shown in FIG. 1 has a first magnetically sensitive element 4 and a magnet 5. The magnet 5 is configured to generate a magnetic field. The magnet 5 may be a permanent magnet which always generates a magnetic field. In particular, the magnet 5 may be a structured thin-film permanent magnet. The magnet 5 has an aspect ratio which is not equal to one. The aspect ratio is defined is as the ratio of the length of the magnet 5 to the width of said magnet. The magnet 5 can accordingly be designed in a rod-like or ellipsoidal manner, for example.

As an alternative, the magnet 5 may be a solenoid which generates a magnetic field only when it is switched on. The magnet 5 can accordingly have a coil through which current flows.

The first magnetically sensitive element 4 is configured to determine the magnetic field at the position of said first magnetically sensitive element. The magnetically sensitive element 4 may be, for example, a Hall element which determines the field strength of the magnetic field on the basis of the Hall effect. As an alternative or in addition, the magnetically sensitive element 4 can determine the magnetic field with the aid of the magnetoresistive effect.

The relative position of the magnetically sensitive element 4 in relation to the magnet 5 can be determined on the basis of this information.

In the exemplary embodiment shown in FIG. 1, the magnet 5 is fastened directly on the movable structure 3 and the magnetically sensitive element 4 is fastened directly on the fixed structure 2. In particular, the magnet 5 cannot move relative to the movable structure 3 and the magnetically sensitive element 4 cannot move relative to the fixed structure 2.

FIG. 1 shows, in the image on the left-hand side, a cross section through the sensor 1 in the xz plane. The image 1 on the right-hand side shows a cross section through the sensor 1 in the xy plane. The z direction is defined as the direction of the surface normal of the movable structure 3. The x and the y direction are arranged respectively perpendicular to the z direction and perpendicular to one another.

FIG. 1 shows the sensor 1 in a state in which the movable structure 3 is in an undeflected state. In this state, no external force acts on the movable structure 3. If a pressure is exerted on the movable structure 3, for example, due to sound waves, the movable structure 3 is deflected relative to the fixed structure 2.

Furthermore, the sensor 1 has a second, a third and a fourth magnetically sensitive element 104, 204, 304 in addition to the first magnetically sensitive element 4. The four magnetically sensitive elements 4, 104, 204, 304 are fastened to the fixed structure 2. The four magnetically sensitive elements 4, 104, 204, 304 are arranged in one plane. Furthermore, the magnet 5 is also arranged in the plane in the undeflected state of the movable structure 3. The sensor 1 allows the position of the movable structure 3 within the plane, which is also called the xy plane, to be unambiguously determined.

If the movable structure 3 moves in a direction perpendicular to the xy plane, the sensor 1 does not allow the z position of the movable structure 3 to be unambiguously determined. In particular, it is not possible to distinguish between whether the movable structure 3 is moving in the positive z direction or in the negative z direction. Here, the positive z direction is the direction from the bottom side of the movable structure 3 to the top side of the movable structure 3, wherein the magnet 5 is arranged on the top side of the movable structure 3 and the bottom side of the movable structure 3 is free of the magnet 5. The negative z direction is directed opposite to the positive z direction.

Furthermore, a comb structure 9 is formed between the movable structure 3 and the fixed structure 2. Electrodes can respectively form on the movable structure 3 and on the fixed structure 2 in the region of this comb structure 9. In particular, the movable structure 3 and the fixed structure 2 can each be composed of a conductive material, so that a voltage can be applied to each of said structures. The movable structure 3 can be electrostatically excited to oscillate by means of said electrodes. As an alternative, it is also possible to provide the movable structure 3 with an electrode structure and a piezoelectric film and to excite said movable structure to oscillate by means of the piezoelectric film. In the case of rate of rotation sensors, the movable structure 3 is made to oscillate in order to determine the rates of rotation.

Furthermore, it is feasible for the movable structure 3 and the fixed structure 2 to in each case form electrodes in the region of the comb structure 9 and for the sensor 1 to be operated in an electrostatic closed-loop process. In this case, a movement of the movable structure 3 is first detected and then an opposing field is applied to the electrodes, said opposing field holding the movable structure 3 still. This closed-loop measurement allows the dynamic behavior of the sensor 1 to be further improved. The comb structure 9 and the embodiments cited in this context are optional configurations which are not necessarily required for functioning of the sensor 1 but which may be advantageous in certain applications.

The sensor 1 shown in FIG. 1 has four magnetically sensitive elements 4, 104, 204, 304 which are interconnected by means of a Wheatstone measuring bridge and therefore are used to measure the position of the movable structure 3. Interconnection by means of the Wheatstone measuring bridge provides the advantages that unambiguous measurement is possible with simple circuitry, and that furthermore a high degree of measurement accuracy is achieved. The Wheatstone measuring bridge is a standard reading method which can be combined with numerous evaluation circuits.

The xy position of the movable structure 3 can already be unambiguously determined using two magnetically sensitive elements 4, 104. Accordingly, in an alternative configuration, the sensor 1 could have only the first and the second magnetically sensitive element 4 and 104.

FIG. 2 shows a second exemplary embodiment of the sensor 1. The image on the left-hand side shows a cross section through the sensor 1 in the xz plane, and the image on the right-hand side shows a cross section through the sensor 1 in the xy plane.

The sensor 1 shown in FIG. 2 differs from the sensor 1 shown in FIG. 1 in that, in an undeflected state of the movable structure 3, the magnet 5 is arranged outside the plane in which the four magnetically sensitive elements 4, 104, 204, 304 are arranged. As a result, the sensor 1 shown in FIG. 2 can unambiguously measure the x, y and z coordinates of the position of the movable structure 3. In particular, the movable structure 3 has a raised portion 10, on which the magnet 5 is arranged, on the top side of said movable structure. The sensor 1 allows the position of the movable structure 3 relative to the fixed structure 2 in the z direction to be unambiguously determined, provided that the magnet 5 does not move in the negative z direction to such an extent that it is located beneath the plane which is spanned by the magnetically sensitive elements 4, 104, 204, 304. In this case, there would be an ambiguous measurement result.

The sensor 1 shown in FIG. 2 has the same number of magnetically sensitive elements 4, 104, 204, 304 and magnets 5 as the sensor 1 shown in FIG. 1 and furthermore additionally allows the z coordinate of the position of the movable structure 3 to be determined.

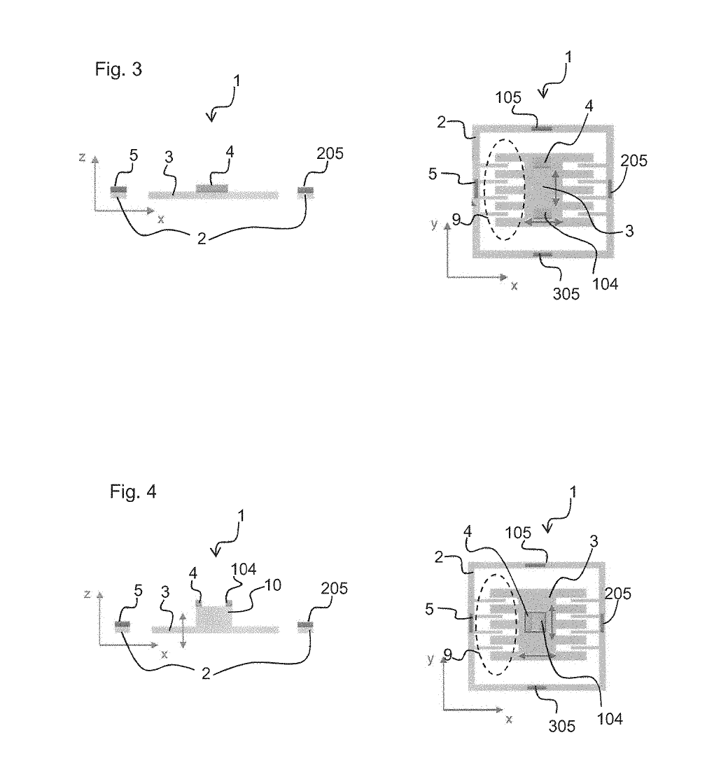

FIG. 3 shows a third exemplary embodiment of the sensor 1. The image on the left-hand side shows a cross section through the xz plane, and the image on the right-hand side shows a cross section through the xy plane.

In comparison to the first exemplary embodiment shown in FIG. 1, the magnetically sensitive elements 4, 104, 204, 304 have been replaced by magnets 5, 105, 205, 305. Furthermore, the magnet 5 has been replaced by two magnetically sensitive elements 4, 104. Accordingly, magnets 5, 105, 205, 305 are now arranged on the fixed structure 2. In particular, the sensor 1 has four magnets 5, 105, 205, 305 which are each arranged on the fixed structure 2 and cannot move relative to the fixed structure 2. Furthermore, two magnetically sensitive elements 4, 104 are arranged on the movable structure 3. The two magnetically sensitive elements 4, 104 cannot move relative to the movable structure 3.

The sensor 1 is configured to determine a relative position of the movable structure 3 in relation to the fixed structure 2 in the xy plane.

FIG. 4 shows a fourth exemplary embodiment of the sensor 1, wherein the image on the left-hand side shows a cross section through the xz plane, and the image on the right-hand side shows a cross section through the xy plane.

The sensor 1 shown in FIG. 4 differs from the sensor 1 shown in FIG. 3 in that, in an undeflected state of the movable structure 3, the magnetically sensitive elements 4, 104 are arranged outside the plane which is spanned by the four magnets 5, 105, 205, 305. The movable structure 3 has a raised portion 10 on which the two magnetically sensitive elements 4, 104 are arranged. The sensor 1 allows the x, y and z coordinates of the position of the movable structure 3 relative to the fixed structure 2 to be determined. It is possible to unambiguously determine the z coordinate provided that the movable structure 3 does not move in the negative z direction to such an extent that the two magnetically sensitive elements 4, 104 are arranged beneath the plane which is spanned by the four magnets 5, 105, 205, 305.

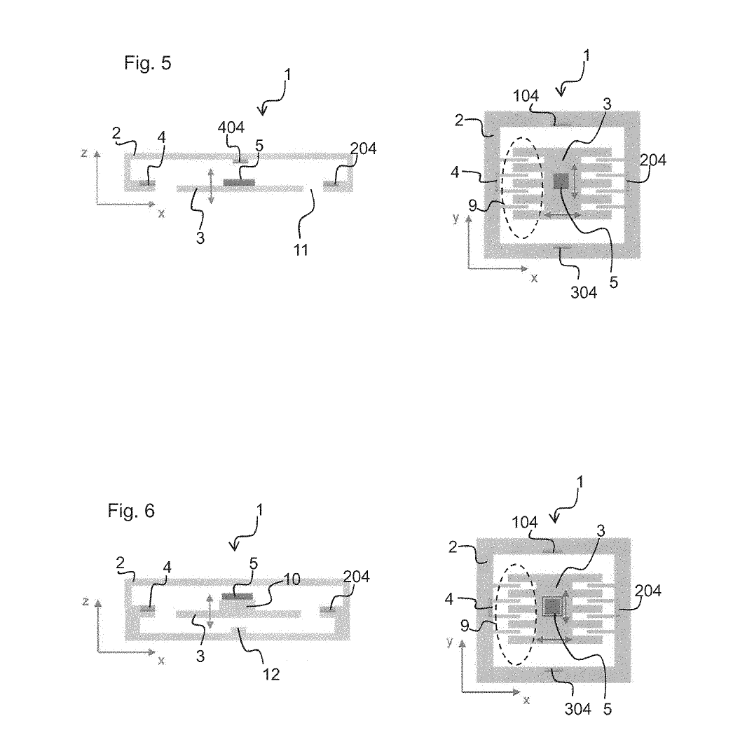

FIG. 5 shows a fifth exemplary embodiment of the sensor 1. The fifth exemplary embodiment differs from the first exemplary embodiment shown in FIG. 1 in that a further magnetically sensitive element 404 is arranged above the magnet 5. The further magnetically sensitive element 404 is accordingly arranged outside the plane in which the first to fourth magnetically sensitive element 4, 104, 204, 304 are arranged. Accordingly, the sensor 1 allows the x, y and z coordinates of the position of the movable structure 3 to be unambiguously determined. In particular, it is possible to unambiguously determine the z coordinate without restrictions. The fixed structure 2 is designed as an open frame which surrounds the movable structure 3 at the sides and the top side and which has an opening 11 on its bottom side.

FIG. 6 shows a sixth exemplary embodiment of the sensor 1. In the sixth exemplary embodiment, four magnetically sensitive elements 4, 104, 204, 304 are arranged in one plane, and furthermore a magnet 5 is fastened on the movable structure 3 outside the plane, wherein the magnet 5 is located outside the plane when the movable structure 3 is in an undeflected state. Furthermore, the sensor 1 has a stop 12 which is configured to limit the movement options of the magnet 5 in such a way that the magnet 5 is always located on a top side of the plane or in the plane.

The fixed structure 2 is designed as a frame which surrounds the movable structure 3 on all sides. The fixed structure 2 is therefore a closed three-dimensional frame which includes a cavity, wherein the movable structure 3 is arranged within the cavity.

Further embodiments of the sensor 1 are feasible. For example, in the fifth and sixth exemplary embodiments as well, the magnetically sensitive elements 4, 104, 204, 304, 404 can be arranged on the movable structure 3 and the magnets 5, 105 can be arranged on the fixed structure 2.

In the exemplary embodiments shown in the figures, the movable structure 3 is always a diaphragm. However, the movable structure 3 can also be designed as a seismic mass.

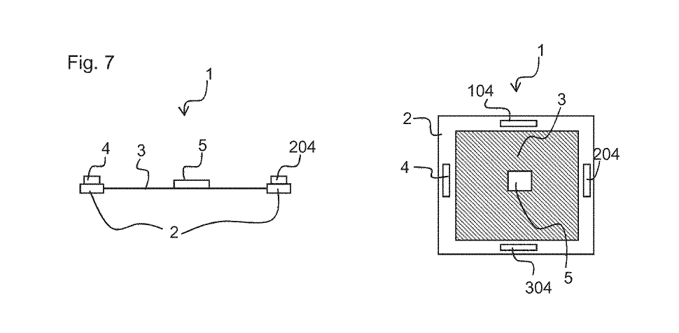

FIG. 7 shows a seventh exemplary embodiment of a sensor 1. The sensor 1 is a sensor for measuring a pressure. The movable structure 3 is also a diaphragm in this sensor 1. Furthermore, the fixed structure 2 is a frame. The edge regions of the movable structure 3 are fastened to the fixed structure 2 in such a way that said edge regions cannot move in the z direction, wherein the z direction is defined as the direction of the surface normal of the movable structure 3. An inner region of the movable structure 3, which inner region adjoins the edge region, can move in the x direction relative to the fixed structure 2.

### LIST OF REFERENCE SYMBOLS

1 Sensor
2 Fixed structure
3 Movable structure
4 First magnetically sensitive elements
5 Magnet
9 Comb structure
10 Raised portion
11 Opening
12 Stop
104 Second magnetically sensitive elements
105 Magnet
204 Third magnetically sensitive elements
205 Magnet
304 Fourth magnetically sensitive elements
305 Magnet
404 Further magnetically sensitive elements

1-15. (canceled)

16. A sensor comprising:
a fixed structure;
a movable structure movable relative to the fixed structure;
a magnet configured to generate a magnetic field; and
a first magnetically sensitive element configured to determine the magnetic field at a position of the first magnetically sensitive element,
wherein the magnet is fastened to the fixed structure and the first magnetically sensitive element is fastened to the movable structure, or
wherein the magnet is fastened to the movable structure and the first magnetically sensitive element is fastened to the fixed structure.

17. The sensor according to claim 16, wherein the sensor is configured to ascertain a relative position of the movable structure in relation to the fixed structure by determining the magnetic field at the position of the first magnetically sensitive element.

18. The sensor according to claim 16, further comprising a second magnetically sensitive element configured to determine the magnetic field at a position of the second magnetically sensitive element.

19. The sensor according to claim 18, wherein the first and second magnetically sensitive elements are arranged in one plane.

20. The sensor according to claim 19, wherein the magnet is arranged outside the plane when the movable structure is in an undeflected state.

21. The sensor according to claim 19, wherein the sensor has a stop which limits movement options of the movable structure in such a way that the magnet is always located on a first side of the plane or in the plane.

22. The sensor according to claim 19, wherein the sensor has a third magnetically sensitive element configured to determine the magnetic field at a position of the third magnetically sensitive element, wherein the third magnetically sensitive element is arranged outside the plane.

23. The sensor according to claim 16, wherein the movable structure is a diaphragm or a seismic mass.

24. The sensor according to claim 16, wherein the sensor is configured to excite the movable structure to oscillate.

25. The sensor according to claim 16, wherein the magnet is a structured thin-film permanent magnet.

26. The sensor according to claim 16, wherein the magnet has a length and a width, and wherein a ratio of the length to the width is not equal to 1.

27. The sensor according to claim 16, wherein the magnet comprises a coil through which current flows.

28. The sensor according to claim 16, further comprising a second movable structure movable relative to the fixed structure, a further magnet configured to generates a further magnetic field, and a second magnetically sensitive element configured to determine the further magnetic field at a position of the second magnetically sensitive element,
wherein the further magnet is fastened to the fixed structure and the second magnetically sensitive element is fastened to the second movable structure, or
wherein the further magnet is fastened to the second movable structure and the second magnetically sensitive element is fastened to the fixed structure.

29. The sensor according to claim 28, further comprising an electrode structure located on the fixed structure and on the second movable structure, the electrode structure being configured to excite the second movable structure to oscillate.

30. The sensor according to claim 16, further comprising structures for measuring a direction of the Earth's magnetic field and/or structures for measuring a pressure.

31. The sensor according to claim 16, wherein the sensor is configured to determine ten degrees of freedom, wherein all of the ten degrees of freedom are ascertainable by a relative position of one or more magnets in relation to one or more magnetically sensitive elements, and wherein either the one or more magnets or the one or more magnetically sensitive elements are arranged on the fixed structure and the respective other elements selected from the group consisting of the one or more magnets and the one or more magnetically sensitive elements are arranged on the movable structure.
